(19) United States
(12) Patent Application Publication
(10) Pub. No.: US 2025/0210305 A1
(43) Pub. Date: Jun. 26, 2025

(54) SPATIALLY TUNABLE INDUCTIVELY COUPLED PLASMA ANTENNA

(71) Applicant: Lam Research Corporation, Fremont, CA (US)

(72) Inventors: Jozef Kudela, West Linn, OR (US); David French, Fort Myers, FL (US)

(73) Assignee: Lam Research Corporation, Fremont, CA (US)

(21) Appl. No.: 18/846,216

(22) PCT Filed: Apr. 10, 2023
(86) PCT No.: PCT/US2023/018089

§ 371 Date: Sep. 11, 2024

Related U.S. Application Data
(60) Provisional application No. 63/363,191, filed on Apr. 19, 2022.

(51) Int. Cl. H01J 37/32; H01L 21/67

(52) U.S. Cl. CPC H01J 37/3211; H01L 21/67069

(57) ABSTRACT

Herein described is an apparatus comprising an inductively coupled plasma (ICP) antenna comprising a plurality of inductances electrically coupled in series, and a capacitor coupled in parallel with an inductance of the plurality of inductances. In at least one embodiment, ICP antenna is to be electromagnetically coupled to a plasma.

### CLAIM FOR PRIORITY

This application is a continuation of, and claims the benefit of priority to U.S. Patent Application No. 63/363,191, filed on Apr. 19, 2022, titled “SPATIALLY TUNABLE INDUCTIVELY COUPLED PLASMA ANTENNA,” and which is incorporated by reference in its entirety.

### BACKGROUND

Process tools are used to perform treatments such as deposition and etching of film on semiconductor wafer substrates. These process tools may utilize plasmas for plasma-enhanced etching and deposition processes. The plasma may be created and sustained by inductive electric fields that are generated and controlled by coils external to the chamber. These coils are coupled with radio frequency voltage sources. It is useful to control plasma parameters that can affect deposition and etch characteristics to enable process uniformity. Process uniformity can help to create semiconductor devices across a substrate with uniform device characteristics. However, with increasing demand for performance and stability of semiconductor devices within a substrate, it is desirable to develop features in inductively coupled plasma coils that can improve local plasma characteristics over the substrate.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale and exact locations. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections characteristic of structures formed by nanofabrication techniques. Further, where considered appropriate, reference labels have been repeated among the figures to indicate corresponding or analogous elements.

FIG. 1 illustrates a cross-sectional view of a plasma processing tool in accordance with at least one embodiment.

FIG. 2A illustrates an electrical schematic of an inductively coupled plasma (ICP) circuit comprising a spatially tunable ICP antenna in accordance with at least one embodiment.

FIG. 2B illustrates an alternative electrical schematic of a spatially tunable ICP antenna circuit comprising an ICP antenna in accordance with at least one embodiment.

FIG. 2C illustrates a further alternative electrical schematic of a spatially tunable ICP antenna circuit comprising an ICP antenna in accordance with at least one embodiment.

FIG. 3A illustrates an isometric view of a spatially tunable ICP antenna in accordance with at least one embodiment.

FIG. 3B illustrates an isometric view of an alternative spatially tunable ICP antenna in accordance with at least one embodiment.

FIG. 4A illustrates a cross-sectional view of a semiconductor process tool comprising a spatially tunable ICP antenna in accordance with at least one embodiment.

FIG. 4B illustrates an exemplary plot of the current ratio between tuned portions and an untuned portion of a spatially tunable ICP antenna as a function of applied frequency, in accordance with at least one embodiment.

FIG. 5 illustrates a flow chart summarizing an exemplary method for tuning a spatially tunable ICP antenna to enable static spatial control of a plasma, in accordance with at least one embodiment.

FIG. 6 illustrates a flow chart summarizing an exemplary method for tuning a spatially tunable ICP antenna to enable dynamic spatial control of a plasma, in accordance with at least one embodiment.

### DETAILED DESCRIPTION

In at least one embodiment, an apparatus and method to enable spatial tuning of radial profile of an inductively coupled plasma (ICP) using a single ICP antenna are disclosed. Here, numerous specific details are set forth, such as structural schemes, to provide a thorough understanding of embodiments of present disclosure. It will be apparent to one skilled in art that embodiments of present disclosure may be practiced without these specific details. In other instances, well-known features, such as gas delivery line tubing fittings, heating elements and snap switches, are described in lesser detail to not obscure embodiments of present disclosure. Furthermore, it is to be understood that at least one embodiment shown in figures is illustrative representations and are not necessarily drawn to scale.

In some instances, well-known methods and devices are shown in block diagram form, rather than in detail, to avoid obscuring at least one embodiment. Reference throughout this specification to “an embodiment” or “one embodiment” or “at least one embodiment” or “some embodiments” means that a particular feature, structure, function, or characteristic described in connection with embodiment is included in at least one embodiment. Thus, appearances of “in an embodiment” or “in one embodiment” or “at least one embodiment” or “some embodiments” in various places throughout this specification are not necessarily referring to a same embodiment. Furthermore, particular features, structures, functions, or characteristics may be combined in any suitable manner in at least one embodiment. For example, a first embodiment may be combined with a second embodiment anywhere particular features, structures, functions, or characteristics associated with first embodiment and second embodiment are not mutually exclusive.

Here, “coupled” and “connected,” along with their derivatives, may be used to describe functional or structural relationships between components. These terms are not intended as synonyms for each other. Rather, in particular embodiments, “connected” may be used to indicate that two or more elements are in direct physical, optical, or electrical contact with each other. Here, “coupled” may be used to indicate that two or more elements are in either direct or indirect (with other intervening elements between them) physical, electrical or in magnetic contact with each other, and/or that two or more elements co-operate or interact with each other (e.g., as in a cause an effect relationship).

Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in context of component assemblies. As used throughout this description, and in claims, a list of items joined by term “at least one of” or “one or more of” can mean any combination of listed terms.

Here, “adjacent” may generally refer to a position of a thing being next to (e.g., immediately next to or close to with one or more things between them) or adjoining another thing (e.g., abutting it).

Unless otherwise specified in explicit context of their use, “substantially equal,” “about equal” and “approximately equal” may generally mean that there is no more than incidental variation between two things so described. In at least one embodiment, such variation is no more than +/−10% of a referred value.

In process tools equipped for plasma-enhanced processes, spatial control of plasma characteristics such as density and energy of charged species, often called plasma density, and electron or ion temperatures, is desirable for obtaining control of etch rates or deposition rates locally on a substrate. In at least one embodiment, radial distribution of plasma density or density of reactive species within a plasma can be controlled by spatially controlling RF power coupling to plasma. RF power coupling in turn can be controlled by tuning antenna coil or antenna-coil elements. In at least one embodiment, a process tool such as a plasma process tool may include a chamber equipped with an inductively coupled plasma (ICP) antenna coil that is coupled to a radio frequency (RF) signal source. In at least one embodiment, ICP antenna is utilized to generate electromagnetic fields which in turn generate an inductive electric field through a transformer action that sustains plasma.

In at least one embodiment, a spatially tuned plasma density may enhance a deposition or etch rate toward periphery of a substrate undergoing process. To this end, some solutions have been developed to tune magnetic fields within certain regions of plasma relative to other regions. Some approaches use multiple coils that are spatially separated and use multiple RF signal sources. Other solutions include multiple coils and multiple outputs from a single source. Another approach is splitting power from a single source output, where power may be routed to multiple coils at different power levels. Other approaches include movable segments of an ICP antenna coil to spatially change coupling by changing distance of coil segment to plasma. Most of these approaches may use elaborate and bulky installations at considerable cost.

To address limitations described herein, in at least one embodiment, a spatially tunable inductively coupled plasma (ICP) antenna is provided. In at least one embodiment, spatially tunable ICP antenna comprises a plurality of discrete inductances or distributed inductances (e.g., segments of a single coil) that are series-coupled. In at least one embodiment, plurality of inductances are segments of a coil. In at least one embodiment, one or more of inductances may be coupled in parallel with a shunt capacitor. In at least one embodiment, parallel combinations of inductances (L) and shunt capacitors (C) form LC tank circuits. In at least one embodiment, a tank circuit has a resonant frequency determined by values of inductance and capacitance. In at least one embodiment, tank circuits comprising portions of a coil may be tuned portions of ICP antenna, where tuning may be accomplished by varying capacitance, inductance, frequency, or a combination of any tuning parameters. In at least one embodiment, portions of coil that are not coupled to a capacitor (or capacitance) may be considered untuned portions of coil. In at least one embodiment, spatially tunable ICP antenna is coupled to a radio frequency (RF) signal source configured to drive current at radio frequency (hereinafter, RF source), delivering RF power into ICP antenna.

In at least one embodiment, at some applied RF frequencies (or tuned capacitor values at a constant frequency), one or more tuned portions on ICP antenna may resonate, developing large circulating currents within associated tank circuit. In at least one embodiment, large circulating currents may develop spatially differentiated magnetic fields across ICP antenna. In at least one embodiment, tuned portions of ICP antenna may generate very strong magnetic fields at some applied RF frequencies relative to adjacent untuned portions of ICP antenna, where smaller line currents may flow. In at least one embodiment, magnetic fields emanating from untuned portions may be weaker than magnetic fields emanating from tuned portions of an IC antenna. In at least one embodiment, relative magnitudes of magnetic field strength in tuned and untuned portions of ICP antenna may be correlated with a ratio of applied RF frequency f to resonant frequency f₀ of tuned portion.

In at least one embodiment, when utilized in a plasma processing tool, spatially tunable ICP antenna may enable tuning of radial distribution of plasma densities in an inductively coupled plasma. In at least one embodiment, localized spatial enhancement of inductively coupled plasma in selected regions are possible by tuning either source frequency, or resonant frequencies of tuned portions of ICP antenna. In at least one embodiment, localized enhancement of radially distributed portions of plasma may equate to increased plasma-assisted etch or deposition rates of corresponding regions of a substrate. In at least one embodiment, increased PECVD (plasma enhanced chemical vapor deposition) or PEALD (plasma enhanced atomic layer deposition) process deposition rates may be enabled in those same regions of substrate.

Here, “coil” may generally refer to a form of an inductance that comprises a wire or other conductor that is wound into one or more turns, generally circular. In at least one embodiment, a coil may be in form of a flat spiral, or a solenoid adjacent to a flat- or dome-tapered dielectric window. In at least one embodiment, geometric factors such as number of turns, spacing between turns, diameter and length of coil, as well as other dimensions such wire thickness, and distance of wire to plasma may also influence inductance of a coil.

Here, “coil segment” may generally refer to a portion of a coil. In at least one embodiment, a coil segment may be contiguous with adjacent coil segments within a coil.

Here, “terminal” may generally refer to end of a conductor or electrical component, such as a wire, which may be a point of connection for other conductors or electrical components. In at least one embodiment, in context of a coil, terminal is an end of a winding. In at least one embodiment, referring to coil segments, a coil segment may comprise a terminal at beginning and an end of a coil segment conductor.

Here, “inductance” may generally refer to a passive electrical device that stores magnetic energy from an electrical current flowing through it. In at least one embodiment, an inductance may comprise a conductor (e.g., a metal wire) that may couple an electrically generated magnetic field into another conductor that is nearby, inducing a voltage and current in second conductor. In at least one embodiment, magnetic field may be generated by currents flowing within first conductor according to Faraday's law of induction. Conductors have property of inductance, which is a function of magnitude of current flowing within conductor and shape or geometry of conductor. While any conductor may be an inductance, some shapes produce a stronger inductance than others. In at least one embodiment, a straight wire may have a small inductance that is dependent on its diameter and length. In at least one embodiment, straight wire may be wound into a coil to multiply inductance by number of windings per unit length, for example, due to mutual additive coupling of magnetic fields between each winding, reinforcing overall magnetic field. In at least one embodiment, magnetic fields from each winding couple, producing a multiplication of magnetic field produced by straight wire according to Ampere's law. In at least one embodiment, a coil may be a planar coil, a helical coil, such as a solenoid or tapered helix.

Here, “capacitor” may generally refer to a passive electrical device that stores electrical charge and electrical energy in form of an electric field. In at least one embodiment, capacitor generally has at least two conductive plates in proximity to one another, separated by a dielectric material. In at least one embodiment, dielectric material may be air (or other gas) or vacuum. In at least one embodiment, dielectric material may generally be a solid or liquid material, such as a polymer, a ceramic, or a semi-liquid electrolyte. In at least one embodiment, opposite electrical charges may accumulate on adjacent plates, forming an electric field extending from plate to plate through dielectric material. In at least one embodiment, electric field can store electrical energy.

Here, “capacitance” may generally refer to a ratio of an amount of electric charge in coulombs stored on plates of a capacitor to a particular voltage is impressed on plates. In at least one embodiment, a capacitance may refer to a capacitive behavior of a metallic structure that is not necessarily intended to be used as a discrete capacitor electrical device.

Here, “inductance” may generally refer to both an electrical circuit element and a physical property of that element. In at least one embodiment, any conductor, including a short piece of straight wire, has property of inductance. In at least one embodiment, inductance is a ratio of a magnetic flux produced by a current flowing through a conductor. In at least one embodiment, a magnetic field is also associated with an inductance when a current is flowing through a conductor. In at least one embodiment, value of inductance of a conductor (e.g., self-inductance) also determines magnitude of a voltage induced on conductor by a changing magnetic flux cutting through conductor. In at least one embodiment, value of inductance is a function of conductor geometry, such as cross-sectional shape and dimensions of conductor, number of turns and dimensions of a solenoid or spiral conductor, and magnetic permeability of a medium surrounding coiled conductor. Here, “inductance” may also generally refer to a distributed inductor, not necessarily a discrete inductor. In at least one embodiment, a discrete inductor is commonly a coil as a lumped circuit element. In at least one embodiment, “inductance” may refer to distributed inductances along an ICP antenna, defined below. In at least one embodiment, inductance may refer to a portion or segment of an ICP antenna, where portion of ICP antenna is not a discrete inductor, but a distributed inductance.

Here, “plasma” may generally refer to a gaseous formation comprising charged particles, such as positively or negatively charged atomic or molecular ions and electrons. In at least one embodiment, plasmas are considered fourth state of matter.

Here, “inductively coupled plasma” (ICP) may generally refer to a plasma that is generated by time-varying magnetic fields emanating from a primary inductance or plasma antenna, generally in form of a coil, conducting a radio frequency (RF) current. In at least one embodiment, a small concentration of ionized atoms or molecules and free electrons within a gas may be generated in a discharge. In at least one embodiment, slightly ionized gas may be regarded as a secondary inductance coupled to plasma antenna, which may be considered primary inductance of a transformer where plasma may be considered secondary inductance of transformer to which primary is coupled. In at least one embodiment, gas may pass through an electromagnetic field produced by an adjacent ICP antenna, where charges are accelerated by time-varying electric fields associated with time-varying magnetic fields (according to Faraday's law of induction and Faraday-Maxwell equation). In at least one embodiment, accelerated electrons may collide with neutral atoms or molecules to produce more ions and secondary electrons, building up plasma density of charged particles. In at least one embodiment, magnitude of particle acceleration and hence collision velocity is proportional to strength of electric fields which in turn are proportional to magnetic field strength. In at least one embodiment, magnetic field strength is proportional to magnitude of current flowing within ICP antenna.

Here, “ICP antenna” may generally refer to an inductance through which an RF current may pass and may radiate RF power to a limited extent as near-field static and propagating electromagnetic fields. In at least one embodiment, RF current flows through ICP antenna, generating an electromagnetic field that couples to a partially ionized gas or to a fully developed plasma. In at least one embodiment, partially ionized gas may develop into a plasma by action of electromagnetic field.

Here, “tuned portion” may generally refer to a portion of an ICP antenna, for example, a coil segment, that is coupled to a parallel capacitor, forming a tank circuit. In at least one embodiment, by virtue of inductance of coil segment and capacitance of parallel capacitor, a tank circuit is tuned to a resonant frequency that is defined by 1/[2p√LC], where L is inductance and C is capacitance.

Here, “untuned portion” may generally refer to a portion of an ICP antenna, for example, a coil segment, that is not coupled to a capacitor to set a resonant frequency. As such, untuned portion may not be resonant at any particular frequency other than a self-resonant frequency that may be determined by a parasitic capacitance. In at least one embodiment, parasitic capacitance is capacitance between windings of coil segment. In at least one embodiment, parasitic capacitance also includes capacitance to nearby conductors. In at least one embodiment, self-resonant frequency may also be determined by native inductance of coil segment. In at least one embodiment, self-resonant frequency may be above or below resonant frequencies of tuned portions.

Here, “tank circuit” may generally refer to a parallel combination of an inductance and a capacitor. In at least one embodiment, tank circuit has a characteristic resonant frequency f₀ that is determined by values of inductance L and capacitance C, where f₀=1/[2p√LC]. In at least one embodiment, a tank circuit has a resonance curve that is a plot of circuit impedance as a function of frequency. In at least one embodiment, curve is non-monotonic in that it has a peak at resonant frequency. In at least one embodiment, sharpness and bandwidth of resonance curve is determined by quality factor Q of circuit. Here, “Q” may be defined as a ratio of energy stored in an electric field and magnetic field of a capacitor and inductance, respectively, to energy dissipated as heat by resistive parts of circuit. In at least one embodiment, resistance may mostly be in inductance (e.g., as copper loss, skin effect), as it may comprise a long piece of thin wire wound into a coil. In at least one embodiment, smaller a resistance of coil, larger is Q. In at least one embodiment, Q may be lowered by insertion of a discrete resistor in series with inductance in tank circuit. In at least one embodiment, resonance curve may be broadened by a low circuit Q (e.g., Q<10), and sharpened by a high circuit Q (e.g., Q>10). In at least one embodiment, tank circuits exhibit very large circulating currents at or near resonance. In at least one embodiment, circulating current may be product of line, or feed current, multiplied by Q. In at least one embodiment, very large voltages may also appear across capacitor and inductance because of large circulating current. In at least one embodiment, at a same time, impedance of tank circuit increases dramatically at or near resonance and becomes purely resistive at f₀. In at least one embodiment, resonant tank circuits can have a very high effective resistance that severely reduces conduction of RF current at f₀. Here, “tank circuit” is derived from circuit's ability to store electrical energy. Tank circuits are frequency-determining components of oscillator circuits and tuned coupling circuits, such as are found in tuned RF amplifier stages.

Here, “dielectric material” may generally refer to a non-electrically conductive material, such as a polymer, a ceramic, glass, wood, etc.

Here, “radio frequency” may generally refer to electromagnetic radiation that oscillates at frequencies in a spectrum that is substantially inclusive of frequencies between 10 kilohertz (kHz) and 1 terahertz (THz, or 1015 Hz). In at least one embodiment, upper limit of radio frequency spectrum may extend to several hundred gigahertz (GHz). Radio frequency as a term is commonly abbreviated to “RF”.

Here, “RF signal source” may generally refer to an electronic device that can generate electrical signals at radio frequency. In at least one embodiment, RF signal source is capable of outputting significant RF current (e.g., 1 ampere rms or greater) at significant voltages. In at least one embodiment, RF signal sources for ICP antennas generally are capable of outputting up to hundreds of amperes at up to several hundred volts, generating significant electrical power.

Here, “process tool” may generally refer to a piece of equipment employed in semiconductor fabrication, also referred to as a “semiconductor process tool” for semiconductor processing. In at least one embodiment, a process tool may generally comprise a vacuum chamber in which processes such as substrate plasma etching or plasma-enhanced material deposition are carried out. In at least one embodiment, other non-plasma related processes may also be performed in a process tool.

Here, “chuck” may generally refer to a stage or platform on which a substrate (e.g., a wafer) may be attached.

Here, “substrate” may generally refer to a wafer comprising a semiconductor (e.g., silicon) or an insulator (e.g., aluminum nitride, silicon carbide, silicon nitride, aluminum oxide, float glass, borosilicate glass, etc.). A wafer may be a slice of monocrystalline semiconductor or insulator. In at least one embodiment, a wafer may also comprise a polycrystalline or an amorphous (glassy) material. In at least one embodiment, a wafer may have a diameter generally ranging between 100 mm to 500 mm, and a thickness generally ranging between 100 microns and 1 mm.

Here, “process chamber” may generally refer to a vacuum chamber of a process tool into which a substrate may be introduced for processing. In at least one embodiment, process chamber may include a chuck for holding substrate. In at least one embodiment, a process chamber may be a plasma etch chamber.

Here, “utility chamber” may generally refer to a chamber or enclosure on a process tool where electronics or other sensitive equipment may be housed and isolated from a process chamber. In at least one embodiment, an ICP antenna may be housed in utility chamber, isolated from generally harsh environment of process chamber. In at least one embodiment, utility chamber may be held under vacuum or at atmospheric pressure.

Here, “spatial control” may generally refer to positional control of a processes. For example, spatial control of a plasma etch or deposition by providing spatially resolved coupling of an ICP antenna to a plasma.

Here, “coupled” may generally refer to direct attachment of one electronic component to another. In at least one embodiment, an electric or magnetic field may couple one component to another, where field is controlled by one component to influence another component in some manner.

Here, “magnetic field” may generally refer to lines of magnetic flux direction and intensity emanating from a magnetized material or current-carrying material.

Here, “plasma-enhanced process” may generally refer to a semiconductor process, for example, where plasma is employed to aid process in some way. In at least one embodiment, a plasma enhanced process is enhanced over a similar or same process without plasma. In at least one embodiment, reactive ion etching and plasma-enhanced chemical vapor deposition or plasma enhance atomic layer deposition are examples of plasma-enhanced processes.

Here, “reactive species” may generally refer to ions or neutral radicals formed in plasma.

Here, “ion” may generally refer to a charged atom or molecule. In context of disclosure, an ion may be a gaseous atom or molecule that loses or gains an electron in plasma.

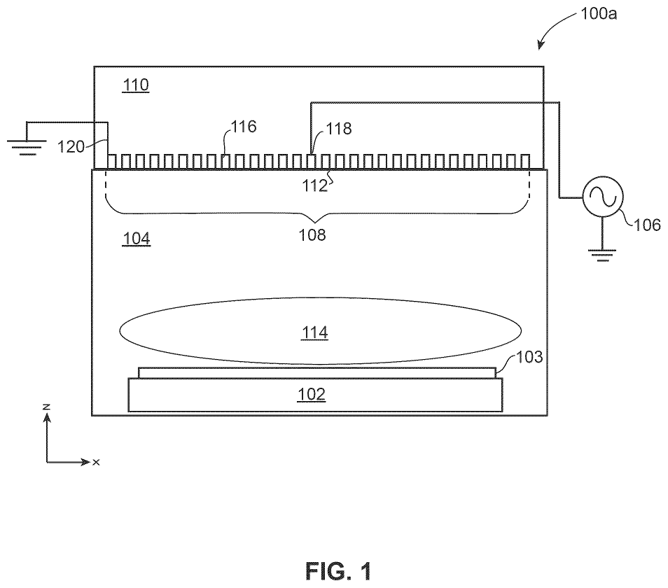

FIG. 1 illustrates a cross-sectional view of plasma processing tool 100a, comprising chuck 102 within process chamber 104, in accordance with at least one embodiment. In at least one embodiment, radio frequency (RF) signal source 106 is coupled to inductively coupled plasma (ICP) antenna 108. In at least one embodiment, ICP antenna 108 is shown as a planar spiral coil (e.g., a “pancake coil”). Individual windings of a flat spiral coil are shown in cross section. In at least one embodiment, wafer 103 may be supported on chuck 102. In at least one embodiment, wafer 103 may undergo a plasma-enhanced deposition or etch process.

In at least one embodiment, ICP antenna 108 may be situated external to process chamber 104. In at least one embodiment, ICP antenna 108 may be wound around process chamber 104, whereby ICP antenna 108 has a helical (e.g., solenoidal) geometry. A solenoid may generally have a cylindrical form factor, where a conductor may be in form of a helical coil. In at least one embodiment, maximal coupling to plasma 114 may be achieved by a planar geometry for ICP antenna 108, as shown, compared to a solenoid or a helical shape.

In at least one embodiment, ICP antenna 108 may be positioned within upper chamber 110 in very close proximity to a dielectric window 112. In at least one embodiment, dielectric window 112 separates upper chamber 110 from process chamber 104. In at least one embodiment, ICP antenna 108 may be enclosed within upper chamber 110 to be isolated from an inductively coupled plasma, such as plasma 114, that may be generated by ICP antenna 108. In at least one embodiment, dielectric window 112 may comprise a dielectric material transparent to electromagnetic fields to permit passage of electromagnetic fields from antenna 108 into process chamber 110.

In at least one embodiment, ICP antenna 108 may generally have a geometry that follows shape of dielectric window 112. In at least one embodiment, ICP antenna 108 may be directly over dielectric window 112 to be in closest proximity to process chamber 104 for magnetic fields to maximally extend into process chamber 104 and reach wafer 103. In at least one embodiment, ICP antenna 108 is planar, following planar geometry of dielectric window 112.

In at least one embodiment, during operation, plasma 114 is formed above wafer 103. In at least one embodiment, plasma 114 may be formed by inductive coupling of electromagnetic fields emanating from ICP antenna 108, interacting with low-pressure gases flowing into process chamber 104. In at least one embodiment, low pressure gases may comprise deposition precursors, etch gases, and inert or reactive carrier gases. In at least one embodiment, time-varying magnetic fields penetrating into process chamber 104 may oscillate at same frequency of RF current flowing within ICP antenna 108. In at least one embodiment, magnetic fields may extend into process chamber 104 through dielectric window 112.

In at least one embodiment, RF currents flowing in ICP antenna 108 may have magnitudes of tens to several hundred amperes. In at least one embodiment, coiled structure of ICP antenna 108 can create large amounts of magnetic flux, injecting large amounts of electromagnetic power into process chamber 104 to ignite and maintain plasma 114. In at least one embodiment, electromagnetic power coupled into plasma 114 creates gaseous ions within plasma 114. In at least one embodiment, ion densities may be increased and decreased by control of power injected into ICP antenna 108. In at least one embodiment, an increased ion density may enable increased deposition or etch rates.

In at least one embodiment, ICP antenna 108 may comprise a hollow copper tube wound into a flat coil to carry cooling water or other fluid, as large RF currents flowing in tubing walls may generate large amounts of heat. In at least one embodiment, due to skin effect for RF currents flowing within conductors, RF currents may generally flow on a surface of tubing. In at least one embodiment, RF current may traverse a very small cross section penetrating several microns or tens or hundreds of microns from surface into interior region of conductor, where skin depth has an inverse proportionality to square root of applied RF frequency. In at least one embodiment, small cross section for current may produce a substantial AC (alternating current) resistance within ICP antenna 108. In at least one embodiment, a large-diameter tubing may be employed to increase RF cross section. In at least one embodiment, ICP antenna 108 comprises multiple windings 116, shown in cross section. In at least one embodiment, ICP antenna 108 may be coupled to RF signal source 106 at an inner terminal 118 and an outer terminal 120.

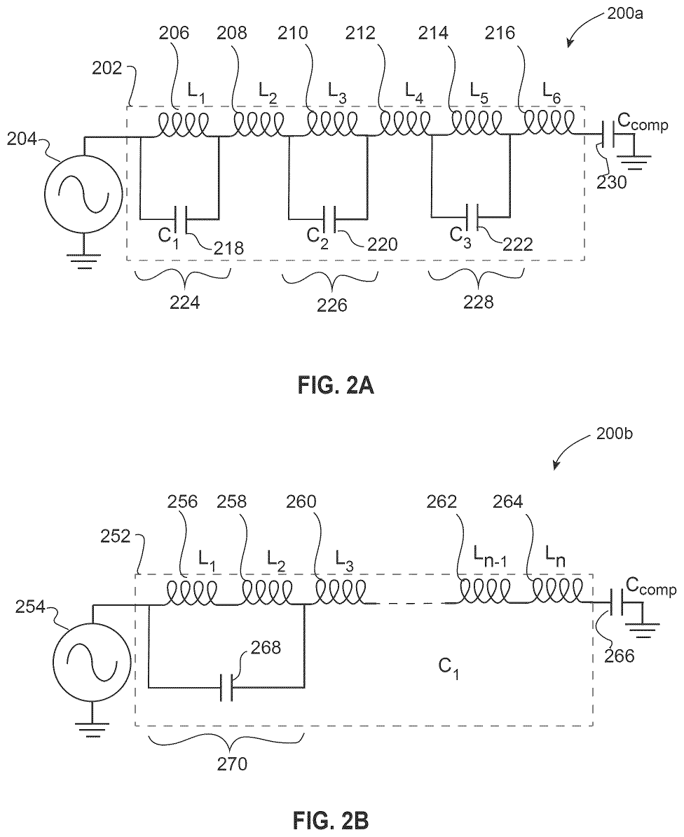

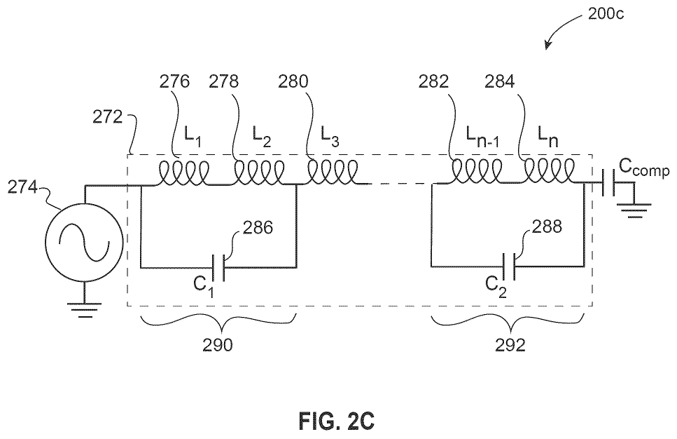

FIG. 2A illustrates an electrical schematic of RF circuit 200a, comprising a spatially tunable inductively coupled plasma (ICP) antenna 202 coupled to RF signal source 204, in accordance with at least one embodiment. In at least one embodiment, ICP antenna 202 comprises a plurality of series-coupled inductances 206, 208, 210, 212, 214 and 216. In at least one embodiment, inductive segments 206-216 are also labeled L1, L2, L3, L4, L5, L6, respectively. Labels L1-L6 may also be considered values of inductance for each inductance 206-216, respectively. In at least one embodiment, inductances 206-216 may be individual discrete inductances, such as individual coils, connected in series. In at least one embodiment, inductances 206-216 may be a series of distributed inductances as consecutive segments of a single coil, where each coil segment has an inductance Ln, where n=1, 2, 3, 4, 5, 6, etc. In at least one embodiment, inductance Ln may be a function of geometrical parameters such as number of windings, spacing between windings, diameter of windings, width of windings, and mutual inductance with adjacent inductances.

In at least one embodiment, shunt capacitors 218, 220, and 222 (labelled C1, C2 and C3, respectively) are coupled in parallel with inductances L1, L3, and L5 (e.g., inductances 206, 210 and 214), where parallel combination of inductance (or segment) and shunt capacitor forms a LC tank circuit. In at least one embodiment, a tank circuit may be a tuned portion of ICP antenna 202. In at least one embodiment, shunt capacitors 218, 220, and 222 may be fixed or variable capacitors. In at least one embodiment, variable capacitors may be any suitable type, such as voltage-controlled capacitors (e.g., a varactor diode), or electronically or mechanically switchable capacitor banks, or a mechanically tunable plate capacitor, such as a butterfly capacitor. In at least one embodiment, any suitable type of variable capacitor may be considered. In at least one embodiment, fixed capacitors may also be high-voltage, high-power types, such as doorknob capacitors.

In at least one embodiment, multiple tank circuits, such as tank circuits 224, 226, and 228, may be included in ICP antenna 202. In at least one embodiment, tank circuits may be adjacent to one another or separated by an untuned portion of ICP antenna 202. In at least one embodiment, an untuned portion is a coil segment that is not coupled to a shunt capacitor.

In at least one embodiment, tank circuits 224-228 are resonant at RF frequencies that are determined by values of inductance and shunt capacitance. In at least one embodiment, bandwidth of individual tuned tank circuits 224-228 may be determined by quality factor Q of circuit. Q may be generally defined as ratio between power stored in electric and magnetic fields of capacitor and inductance, respectively, and power dissipated as heat due to resistive losses of tank circuit, and plasma. In at least one embodiment, tank circuits may derive their name from their ability to store large amounts of electrical energy. In at least one embodiment, large Q factors (e.g., Q>20) generally equate to highly tuned circuits having narrow bandwidths and sharp resonances, whereas lower Q factors (e.g., Q<10) generally equate to larger bandwidths and less sharp resonances. In at least one embodiment, most of resistive loss within a tuned tank circuit is due to series resistance of inductance or plasma.

Parallel tuned circuits also develop high impedances at or near resonance. At resonance of a high-Q tank circuit, impedance may be from several tens to hundreds of thousands of ohms, and can be effectively forming an open circuit to RF at or close to resonant frequency. In addition to high impedance of a resonant tank circuit, large amounts of stored electrical energy may manifest as very large circulating currents flowing within tank circuit. Large circulating currents are created by continuous feed of line current into tank circuit, and buildup of energy stored within electric and magnetic fields of capacitor and inductance components. Circulating current may be product of Q and line current, where line current is current fed into tank circuit. For line currents of several amperes, circulating current within a tank circuit may be as high as several hundreds of amperes, depending on value of Q of circuit and feed RF current. Very large circulating currents may cause substantial heating of inductance within tank circuit or adjacent plasma. In at least one embodiment, very large voltages (e.g., thousands of volts) may exist across capacitor and inductance, potentially causing arcing. Components in tank circuits are designed to withstand exceptionally large currents and voltages, adding to overall costs.

In at least one embodiment, frequency of RF current output from RF signal source 204 may be adjusted to be near resonant frequency of a particular tuned tank circuit. In at least one embodiment, RF current may be tuned to resonant frequency of any of tank circuits 224, 226, and 228. In at least one embodiment, individual tank circuits may have different resonant frequencies, or two or more tank circuits may be tuned to same resonant frequency or have close resonant frequencies. In at least one embodiment, large circulating currents in resonant tank circuit or circuits generate large magnetic fields that may couple to a plasma, such as plasma 114 shown in FIG. 1. In at least one embodiment, a large amount of power from individual rank circuits may be coupled to plasma. In at least one embodiment, individual tank circuits may have different physical locations on ICP antenna 202, enabling spatially differentiated coupling of local magnetic fields to plasma.

In at least one embodiment, ICP antenna 202 may be engineered to apply high power to a first portion of a plasma generated within a processing chamber, such as process chamber 104 shown in FIG. 1, where low power may be applied to a second portion of plasma. In at least one embodiment, within regions of high power, plasma may have a higher plasma density. In at least one embodiment, higher ion densities in regions of plasma may increase etch rates, for example, or deposition rates over desired portions of an etch substrate. In at least one embodiment, spatial differentiation of ICP power application to a plasma may enable designs of ICP antenna 202 to tailor a plasma to have higher plasma density over desired portions of a substrate, for example. In at least one embodiment, ICP antenna may be designed according to process criteria.

In at least one embodiment, inductances 208, 212, and 216 are not coupled to a capacitor, and may simply couple adjacent tuned tank circuits. In at least one embodiment, inductances 208, 212, and 216 are untuned segments of a single coil between tuned segments (e.g., tank circuits). In at least one embodiment, provision of untuned segments or portions of ICP antenna 202 may advantageously decouple adjacent tuned tank circuits 224, 226, and 228.

In at least one embodiment, ICP antenna 202 is optionally series-coupled to an external series capacitor 230. In at least one embodiment, series capacitor (or capacitance) 230 may serve to provide a means to reduce input impedance of ICP antenna 202. In at least one embodiment, input impedance of ICP antenna 202 may comprise mostly inductive reactance, proportional to total inductance of ICP antenna 202. In at least one embodiment, series capacitor 230 may serve to reduce overall inductive reactance of ICP antenna 202 by providing a capacitive reactance. Capacitive reactance is inversely proportional to value of capacitance and frequency, and has opposite sign to inductive reactance. As such, two reactances combined in series are opposed and may be subtracted from one another. In at least one embodiment, more than one series capacitors may be employed in a circuit, and may also be distributed between series inductances.

In at least one embodiment, reduction of input impedance of ICP antenna 202 may result in lower output voltages from RF signal source 204 to produce same output currents for a given power output. In at least one embodiment, an impedance matching network (not shown) may be necessary to match output impedance of RF signal source 204 with input impedance of ICP antenna 202 to maximize power transfer. In at least one embodiment, output impedance of RF signal source 204 may be 50 ohms (mostly resistive, for example), whereas input impedance of ICP antenna 202 may be several tens of ohms to several hundreds of ohms, mostly reactive. In at least one embodiment, matching network (not shown) may be inserted between RF signal source 204 and ICP antenna 202 to match impedances for maximum power transfer. Lower antenna input impedance may equate to lower output voltage from antenna side of matching network, which may reduce possibilities of arcing, etc., lessening costs associated with matching circuit components.

FIG. 2B illustrates an electrical schematic of an alternative ICP antenna circuit 200b, comprising ICP antenna 252 coupled to RF signal source 254, in accordance with at least one embodiment. In at least one embodiment, spatially tunable ICP antenna 252 comprises series-coupled inductances 256, 258, 260, 262, and 264. In at least one embodiment, inductances 256-264 may be a plurality of discrete inductances or a plurality of segments of a single inductance or an inductive portion of a ICP antenna 252. In at least one embodiment, series capacitor 266 may be coupled to a terminal of ICP antenna 252. In at least one embodiment, series capacitor 266 may be adjusted to control antenna impedance. In at least one embodiment, parallel capacitor 268 is coupled across a pair of inductances comprising inductance 256 and 258. While schematic indicates that inductances 256 and 258 are adjacent, they may be separated by a non-inductive component, such as a wire or a capacitor, in accordance with at least one embodiment.

In at least one embodiment, inductances 256 to 260 may also be separated from inductances 262 and 264 by a distance sufficient to reduce magnetic coupling and mutual inductance to a sufficiently low value. Mutual inductance may be defined as combined influence of magnetic fields from one inductance on other. In at least one embodiment, magnetic field vectors from each magnetic field may add or subtract, respectively increasing or decreasing effective inductances of both coupled inductances. Mutual inductance also depends on degree of coupling between two adjacent inductances. Coupling coefficient decreases with increasing distance, for example. In at least one embodiment, by physically separating adjacent inductances, degree of coupling and therefore mutual inductance is diminished.

In at least one embodiment, magnetic shielding or orthogonal placement may also sufficiently reduce mutual inductance to zero or near zero. In at least one embodiment, it may be desired to reduce mutual inductance to a small value. In addition to physical separation as described, in at least one embodiment, mutual inductance may also be reduced by magnetic shielding or by orthogonality. In at least one embodiment, using magnetic shielding or orthogonality, two or more inductances may be in close proximity, but oriented such that their magnetic field vectors are mutually orthogonal. Magnetic coupling may be reduced to near zero in such a configuration, in accordance with at least one embodiment. In at least one embodiment, magnetic shielding may be accomplished by placement of inductance within a non-ferromagnetic metal can, or by using ferromagnetic can or walls, where ferromagnetic material can be conductive or non-conductive, such as MgZn or NiZn ferrites, or magnets.

In at least one embodiment, capacitor 268 may be shunted (e.g., parallel-coupled) across inductances 256 and 258 to form a parallel tank circuit 270. In at least one embodiment, tank circuit 270 may be spatially located along ICP antenna 252 to coincide with a spatial location on a chuck (e.g., chuck 102) within a process chamber (e.g., process chamber 104, FIG. 1) below ICP antenna 252. In at least one embodiment, capacitor 268 is a fixed capacitor. In at least one embodiment, capacitor 268 is a variable capacitor.

In at least one embodiment, resonant frequency of a tank circuit may be expressed by 1/[2p√LC], where L is inductance and C capacitance of tank circuit. In at least one embodiment, multiple inductances included in a tank circuit may be combined to achieve a specific resonant frequency with a given parallel capacitor. In at least one embodiment, capacitor 268 may be shunted across a single or multiple inductances, such as inductances 262 and 264, to cover desired spatial area of plasma chamber or to achieve a lower resonant frequency than may be possible with a single inductance. In at least one embodiment, a tank circuit, such as tank circuit 270, may be chosen by its spatial position along ICP antenna 252. While at least one embodiment shows capacitor 268 shunted across inductances 256 and 258, capacitor 268 may be shunted across any other group of inductances, such as pair of inductances 262 and 264. Inductances 262 and 264 may adjacent to one another and be located at different spatial positions along ICP antenna 252.

During operation, in at least one embodiment, RF signal source 254 may be tuned to a frequency at or near resonant frequency of tank circuit 270, causing it to strongly resonate. In at least one embodiment, resulting large circulating current within tank circuit 270 may generate a strong magnetic field that may be substantially localized at antenna position along ICP antenna 252. In at least one embodiment, magnetic fields emanating from untuned portion of ICP antenna 252, where no tank circuit is present, may be significantly weaker than field generated by tank circuit 270 by comparison. In at least one embodiment, strong magnetic field may couple to a specific spatial region of plasma during operation, creating a spatially localized high ion density within plasma region, which may correlate spatially to coordinates on a substrate when substrate is clamped to chuck in process chamber. In at least one embodiment, if an etch or deposition process is underway, etch or deposition rate at spatial location on substrate may be enhanced relative to neighboring regions.

In at least one embodiment, capacitor 268 may be a variable capacitor and source frequency is fixed. In at least one embodiment, as a variable capacitor, capacitance of capacitor 268 may be adjusted or tuned to bring tank circuit 270 into resonance or near resonance at a fixed applied frequency of RF voltage output by RF signal source 254. In at least one embodiment, tank circuit may be tuned to be within, for example, 50% to 90% of applied frequency (e.g., on both sides of resonance curve). Within this range, in at least one embodiment, strong circulating currents may be generated. In at least one embodiment, depending on circuit Q, resonance curve of tank circuit 270 may steeply rise when resonant frequency of tank circuit is tuned to be within 5% of applied frequency. For resonant frequencies that are within 2% of applied frequency, circuit response may be unpredictable, and may manifest as difficult and unpredictable spatial control of plasma coupled to ICP antenna 252. In addition, extremely high parallel impedance may effectively block line current from reaching other portions of ICP antenna 252. In at least one embodiment, applied frequency or resonant frequency of tank circuit 270 may be continuously adjustable to values that allow a relatively small enhancement of spatially localized magnetic coupling relative to untuned portion of ICP antenna 252.

Above description may also be reversed when capacitor 268 has a fixed capacitance, in accordance with at least one embodiment. In at least one embodiment, resonant frequency of tank circuit 270 is also fixed by employment of capacitor 268, which has a fixed capacitance. In at least one embodiment, an applied frequency of RF current output from RF signal source 254 may be tuned to near resonant frequency of tank circuit 270.

FIG. 2C illustrates an electrical schematic of a further alternative ICP antenna circuit 200c, in at least one embodiment. In at least one embodiment, spatially tunable ICP antenna 272 comprises inductances 276, 278, 280, 282, and 284 in series. In at least one embodiment, ICP antenna 272 also comprises tank circuit 290 and tank circuit 292, representing multiple tuned circuits spatially distributed along ICP antenna 272. In at least one embodiment, tank circuit 290 comprises capacitor 286 coupled in parallel to inductances 276 and 278, representing multiple inductances. In at least one embodiment, inductance 276 may be immediately adjacent to inductance 278, where two inductances may be strongly coupled, or physically separated for weak coupling. In at least one embodiment, inductance 276 and 278 may also be spatially close but magnetically shielded or orthogonal, as described above. In at least one embodiment, combination of inductances 276 and 278 may be chosen to provide a larger inductance in parallel with capacitor 286 than could be possible with only one inductance. In at least one embodiment, a lower resonant frequency of tank circuit 290 may be achieved.

Likewise, in at least one embodiment, tank circuit 292 comprises capacitor 288 in parallel with inductances 282 and 284. In at least one embodiment, tank circuit 292 may be described in a similar manner as tank circuit 290 above. In at least one embodiment, tank circuit 292 may be located at a different spatial position than tank circuit 290 with an untuned portion of ICP antenna 272 comprising inductance 280 between two tank circuits. In at least one embodiment, tank circuit 292 may have a different resonant frequency than tank circuit 290.

In at least one embodiment, frequency response of tank circuits 290 and 292 may be controlled by either tuning RF signal source 274 or by adjustment of capacitors 286 and 288 (as variable capacitors). In at least one embodiment, by tuning either source frequency or tank circuit resonance, or both, depending on desired speed of adjustment or tuning, large circulating currents may be generated in both tank circuits 290 and 292 simultaneously, resulting in spatially localized strong magnetic coupling to a plasma that is coupled to ICP antenna 272.

In at least one embodiment, resonant frequencies of tank circuits 290 and 292 may be disparate, where a first tank circuit resonates at a first frequency, and a second tank circuit resonates at a second frequency. In at least one embodiment, applied frequency may be tuned to cause first tank circuit to strongly resonate, while second tank circuit may exhibit a weak resonance. In at least one embodiment, magnetic coupling from tank circuit 290 may be strong to a plasma coupled to ICP antenna 272, whereas magnetic coupling from tank circuit 292 may be weaker, but still stronger than coupling from untuned portion. In at least one embodiment, resonances may enable spatial control of plasma densities. In at least one embodiment, plasma densities may be significantly proportional to plasma etch rates or plasma enhanced deposition rates, for example.

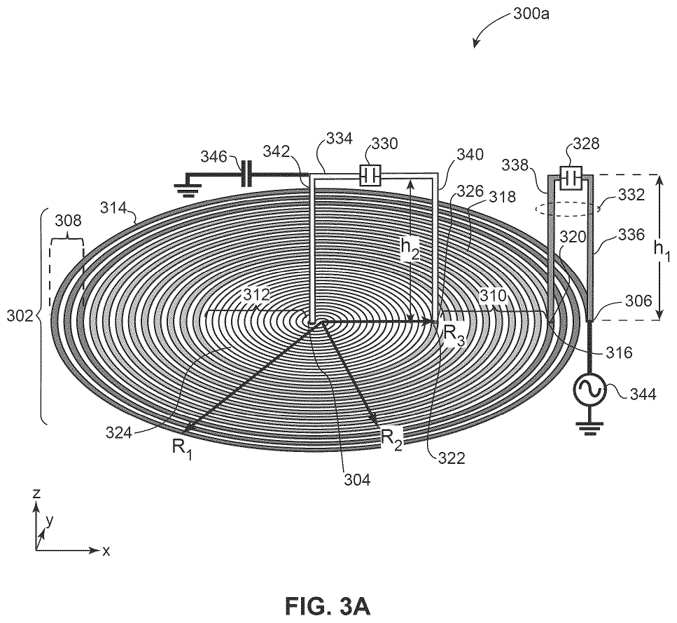

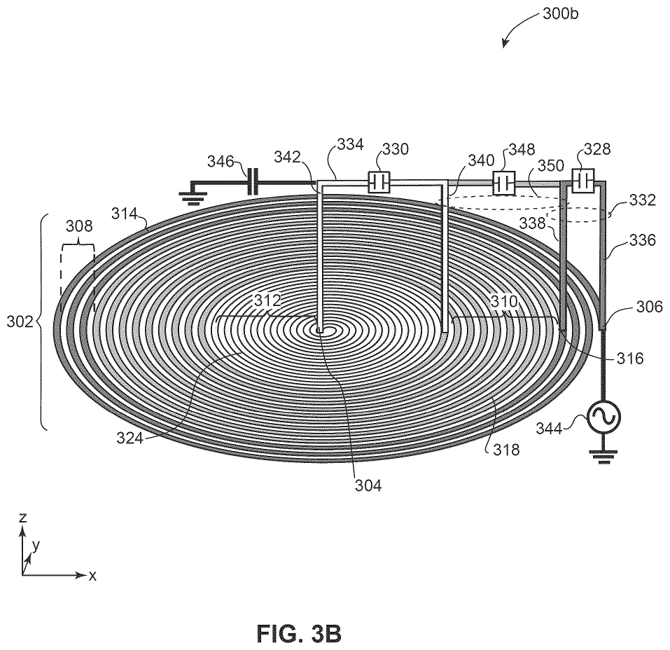

FIG. 3A illustrates a physical embodiment of circuits described in FIGS. 2A-2C, in accordance with at least one embodiment. FIG. 3A shows an isometric view of spatially tunable ICP antenna 300a, comprising coil 302, having an inductance LT. In at least one embodiment, coil 302 is shown as a planar spiral coil that comprises inner terminal 304 and outer terminal 306. While inner terminal 304 is substantially at center of coil 302, in at least one embodiment, inner terminal 304 may be at a non-zero radial distance from center of coil 302. While coil segment 310 is shown as a spiral coil segment, in at least one embodiment, coil segment 310 may comprise a short conductor to directly couple coil segment 308 to coil segment 312.

For example, coil segment 310 may comprise a straight segment of wire or portion of coil conductor to bridge a gap between coil segments 308 and 312. In at least one embodiment, coil segment 310 may comprise a solid annular sheet of conductor spanning a gap between coil segment 308 and 312. In at least one embodiment, coil segment 310 comprises a continuation of windings 314 between windings of coil segment 308 and 312. In at least one embodiment, between inner terminal 304 and outer terminal 306 is a plurality of coil segments 308, 310, and 312 electrically coupled in series.

In at least one embodiment, coil segments 308, 310, and 312 may be substantially concentric, where coil segment 308 is outermost coil segment at periphery of coil 302. In at least one embodiment, coil segment 310 may be an intermediate coil segment of coil 302, and coil segment 312 may be an innermost coil segment of coil 302. Here, individual coil segments 308, 310, and 312 are shown with different gray shading to help distinguish them. In at least one embodiment, individual coil segments comprise multiple windings 314, enabling coil segments 308, 310, and 312 to exhibit inductances L1, L2, and L3, respectively. Sum of inductances L1, L2, and L3 may substantially equal LT.

In at least one embodiment, inductance L of a planar coil may be expressed as L (uH)=kN²A²/(30A−11Di), where k is a proportionality factor, N is number of windings, Di is inner diameter of coil, A=[Di+N(W+S)]/2, where W is width of winding and S is distance between windings. Here, dimensions are in inches while inductance L is expressed in microhenries (uH).

In at least one embodiment, coil segment 308 comprises windings 314 between outer terminal 306 at radius R1 at periphery of coil 302, and first interconnecting terminal 316 at radius R2. In at least one embodiment, coil segment 310 may occupy an intermediate portion of coil 302. In at least one embodiment, coil segment 310 comprises windings 318 between second interconnecting terminal 320 at radius R2 and third interconnecting terminal 322 at radius R2. In at least one embodiment, second interconnecting terminal 320 may abut first interconnecting terminal 316 at radius R2. In at least one embodiment, coil segment 312 comprises windings 324 between fourth interconnecting terminal 326 at radius R3 and inner terminal 304. In at least one embodiment, fourth interconnecting terminal 326 may abut third interconnecting terminal 322. While inner terminal 304 may be substantially at center of coil 302, in at least one embodiment, inner terminal 304 may be located at a substantial radial distance from center of coil 302.

In at least one embodiment, ICP antenna 300a further comprises capacitors 328 and 330, coupled in parallel to coil segment 308 and 312, respectively. In at least one embodiment, capacitors 328 and 330 are represented schematically by capacitor symbols, indicating that capacitors 328 and 330 may be any type of suitable fixed or variable capacitor. In some embodiments, capacitors 328 and 330 may have different or substantially identical fixed capacitances. In at least one embodiment, one or both capacitors 328 and 330 may be variable capacitors having independently tunable capacitances.

While two of three coil segments 308 and 312 coupled in parallel to capacitors 328 and 330, respectively, in at least one embodiment, any of coil segments 308, 310, and 312 may be parallel coupled to any one of capacitors 328 or 330. In at least one embodiment, parallel combination of coil segment 308 and capacitor 328 comprises first tank circuit 332. In at least one embodiment, parallel combination of coil segment 312 and capacitor 330 comprises second tank circuit 334.

In at least one embodiment, capacitors 328 and 330 may be physically offset from plane of coil 302, where they may be above or below plane of coil 302. Here, plane of coil is in x-y plane of figure. Z axis runs above and below coil 302. Here, “above” and “below” may be relative terms relating to orientation of coil 302. For example, in a semiconductor processing tool, coil 302 may be oriented in a substantially horizontal configuration with respect to vertical. In other orientations, “below” may generally refer to side of coil facing a plasma coupled to it. Here, “above” may generally refer to side of coil facing away from plasma.

In at least one embodiment, capacitor 328 may be coupled to coil segment 308 at outer terminal 306 and first interconnecting terminal 316 by leads 336 and 338. In at least one embodiment, leads 336 and 338 may have an offset h₁ from plane of coil 302. In at least one embodiment, capacitor 330 may be coupled to coil segment 312 by leads 340 and 342 attached to interconnecting terminal 326 and inner terminal 304 of coil 302. In at least one embodiment, leads 340 and 342 may have an offset h₂ from plane of coil 302. In at least one embodiment, offsets h₁ and h₂ may be substantially equal.

In at least one embodiment, a RF signal source 344 may be coupled to ICP antenna 300a at outer terminal 306 at radius R1, coupling directly to coil segment 308, located at periphery of ICP antenna 300a. In at least one embodiment, RF line current may flow into tank circuit 332 from RF signal source 344. In at least one embodiment, tank circuit 332 may be a first tuned portion of ICP antenna 300a, operable to resonate at a first frequency. In at least one embodiment, RF current may then continue to flow through coil segment 310, joined to coil segment 308 by abutting first and second interconnecting terminals 316 and 320 at radius R2. In at least one embodiment, coil segment 310 is not coupled to a parallel capacitor, therefore is not part of a tank circuit. Aside from any self-resonance that may be inherent in coil segment 310, coil segment 310 may be an untuned portion of ICP antenna 300a.

In at least one embodiment, RF current may continue to flow into coil segment 312 through abutted third and fourth interconnecting terminals 322 and 326 at radius R3. In at least one embodiment, coil segment 312 is part of tank circuit 334, comprising capacitor 330 coupled in parallel to coil segment 312. In at least one embodiment, coil segment 312 may be a second tuned portion of ICP antenna 300a, operable to resonate at a second RF frequency. In at least one embodiment, RF current may exit coil 302 at inner terminal 304, returning to RF signal source 344. In at least one embodiment, a series capacitor 346 may be inserted between terminal 304 and RF signal source 344 to provide a capacitive reactance countering inductive reactance of ICP antenna 300a. In at least one embodiment, reduction of inductive reactance may also lower input impedance to ICP antenna 300a, enabling reduction of drive voltage output from RF signal source 344 and/or an impedance matching network (not shown) that may be inserted between RF signal source 344 and terminal 306. In at least one embodiment, capacitor 346 may be a fixed or variable capacitor.

FIG. 3B illustrates an isometric view of an alternative spatially tunable ICP antenna 300b, comprising coil 302, in accordance with at least one embodiment. In at least one embodiment, coil segment 310 is coupled to a third capacitor 348. In at least one embodiment, coil segment 310 is intermediate between coil segment 308 at periphery of coil 302 and coil segment 312, innermost coil segment. In at least one embodiment, parallel combination of coil segment 310 and capacitor 348 provides a third tank circuit 350 between tank circuit 332 and tank circuit 334. In at least one embodiment, as coil segment 310 is part of tank circuit 350, coil segment 310 may be considered a third tuned portion of ICP antenna 300b, where coil segment 308 is first tuned portion and coil segment 312 is second tuned portion.

In at least one embodiment, first, second and third tuned portions may be tuned to resonate at a first, second and third RF frequency, respectively, where first, second and third resonant RF frequencies may be substantially different. In at least one embodiment, any two of first, second or third RF frequencies may be substantially identical. In at least one embodiment, first, second and third RF frequencies may be selected to create regions of stronger and weaker spatial coupling to an inductively coupled plasma coupled to ICP antenna 300b, as described earlier, enabling spatial control of ion densities within plasma.

In at least one embodiment, coil segment 310 may be near adjacent coil segments 308 and 312 and therefore may couple magnetically. In at least one embodiment, mutual inductance between coil segments may be used to advantage by augmenting or diminishing self-inductance of individual coil segments 308, 310, and 312. In at least one embodiment, magnetic coupling may be mitigated if so desired by insertion of magnetic shields between coil segments. In at least one embodiment, shields may comprise thin foils or sheets of ferromagnetic metals, such as non-stainless steel, and may be disposed orthogonally to plane of coil 302 to prevent magnetic field lines originating from one coil segment from crossing over to adjacent coil segments.

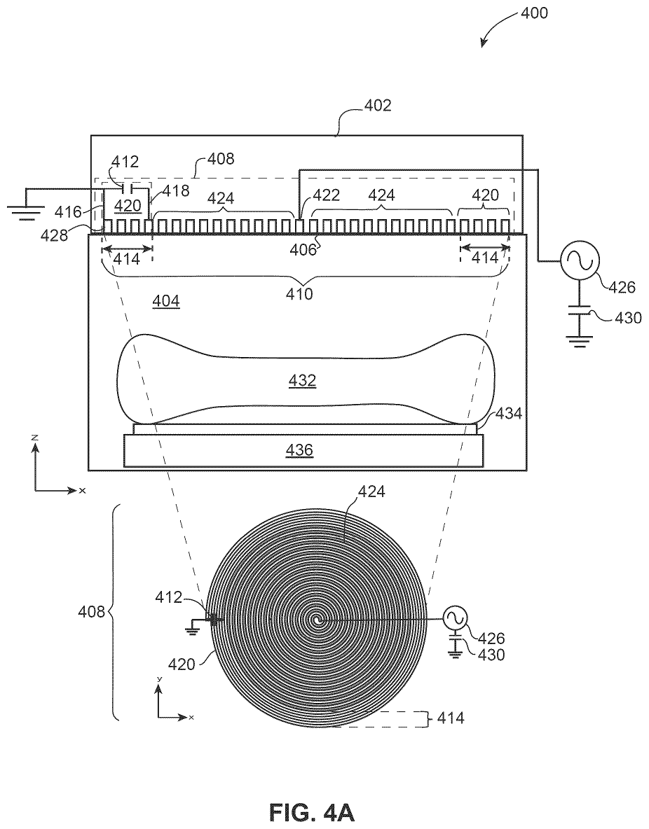

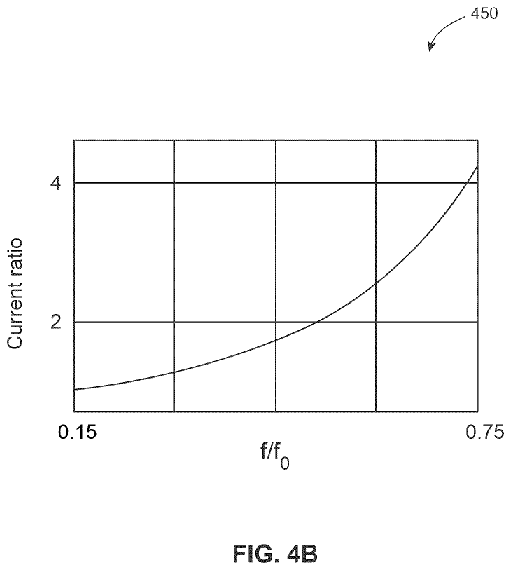

FIG. 4A illustrates a cross-sectional view of semiconductor process tool 400 comprising a spatially tunable ICP antenna, comprising utility chamber 402 and plasma chamber 404 over and adjacent to utility chamber 402, in accordance with at least one embodiment. In at least one embodiment, plasma chamber 404 may be separated from utility chamber 402 by a wall 406 comprising a dielectric material. Wall 406 may also be referred to as dielectric window 406, as it may be substantially transparent to RF electromagnetic fields.

In at least one embodiment, semiconductor process tool 400 may comprise a spatially tunable ICP antenna 408 within utility chamber 402. In at least one embodiment, ICP antenna 408 may be any one of ICP antennas 300a or 300b, for example, described earlier. In at least one embodiment, ICP antenna 408 may comprise a planar spiral coil 410. In at least one embodiment, coil 410 may be immediately adjacent to dielectric window 406, as shown. In at least one embodiment, ICP antenna 408 may further comprise shunt capacitor 412 coupled in parallel (e.g., shunting) coil segment 414 within utility chamber 402. In at least one embodiment, shunt capacitor 412 may be positioned above coil 410. In at least one embodiment, during operation, utility chamber 402 may be under vacuum or hold an inert or reactive gas, or air at atmospheric pressure and room temperature. In at least one embodiment, utility chamber 402 may serve to isolate ICP antenna 408 and associated electronic components from exposure to plasmas and harsh environment that may be present in plasma chamber 404 during operation.

As noted above, shunt capacitor 412 may be coupled in parallel to coil segment 414. In at least one embodiment, coil segment 414 is at periphery of coil 410. In at least one embodiment, capacitor 412 may be connected to coil segment through leads 416 and 418. In at least one embodiment, parallel combination of shunt capacitor 412 with coil segment 414 form a tuned portion 420 of ICP antenna 408. In at least one embodiment, a region of coil 410 that extends between inner terminal 422 of coil 410 and lead 418 is not shunted by a capacitor, constituting untuned portion 424 of ICP antenna 408.

In at least one embodiment, semiconductor process tool 400 may further comprise RF signal source 426. In at least one embodiment, RF signal source 426 is coupled to inner terminal 422 of coil 410 (also of ICP antenna 408). In at least one embodiment, RF signal source 426 may equally be coupled to outer terminal 428 of coil 410. In at least one embodiment, series capacitor 430 may optionally be included in ICP antenna circuit as described earlier. In at least one embodiment, series capacitor 430 may be coupled to outer terminal 428 of coil 410, as shown, returning current to RF signal source 426.

In at least one embodiment, during operation, ICP antenna 408 may generate and maintain inductively coupled plasma 432 (hereinafter plasma 432) electromagnetically coupled to ICP antenna 408. In at least one embodiment, plasma 432 is formed over wafer 434 mounted on pedestal 436. In at least one embodiment, lateral extent of plasma 432 may be approximately diameter of coil 410. In an example of an effect of spatially tuned coupling, plasma 432 is shown as an ion density profile. Here, illustrated profile depicts a radial distribution of ion density, where ion density profile of plasma 432 is represented as thickness of cross section. In at least one embodiment, plasma 432 is shown to have a bone-shaped ion density profile in x-z plane, representing a radial ion density profile. In at least one embodiment, ion density distribution shown in FIG. 4A depicts an increasing ion density toward periphery of plasma 432 relative to an interior region of plasma 432.

In at least one embodiment, a higher ion density toward periphery of plasma 432 may increase deposition rates for PECVD film deposition at periphery of plasma 432. In at least one embodiment, periphery of plasma 432 is electromagnetically coupled to tuned portion 420. In at least one embodiment, central portion of plasma 432 is electromagnetically coupled to untuned portion 424. In at least one embodiment, ICP antenna 408 may comprise multiple tuned portions and untuned portions, enabling plasma 432 to develop a more complex profile than shown in FIG. 4A.

In x-y plane, plasma 432 may also have an approximately circular azimuthal envelope, approximating circular shape of coil 410, for example. In at least one embodiment, tuning of applied frequency from RF signal source 426 or tuning tuned portions of ICP antenna 408 enables spatial control of plasma ion density. In at least one embodiment, by tuning either applied frequency or resonant frequency of tuned portion 420 to bring it into resonance, ion density in peripheral region of plasma 432 may be significantly enhanced relative to interior region of plasma 432.

In at least one embodiment, shunt capacitor 412 is a fixed capacitor. In at least one embodiment, capacitance of shunt capacitor 412 may be predetermined by inductance of coil segment 414 to set a particular resonant frequency of tuned portion 420. In at least one embodiment, shunt capacitor 412 may be a variable capacitor, whereby capacitance of shunt capacitor 412 may be adjusted either manually or dynamically to tune a resonant frequency of tuned portion 420 according to process requirements. In at least one embodiment, resonant frequency may be tuned within limits of a variable capacitance range of shunt capacitor 412. In at least one embodiment, by tuning either applied frequency from RF signal source 426, or by tuning resonant frequency of tuned portion 420, ion density in peripheral region of plasma 432 may be significantly enhanced or de-enhanced relative to interior of plasma 432. In at least one embodiment, tuning may be performed by automated means or by operator discretion. For example, shunt capacitor 412 may be fixed, and frequency may be swept or changed systematically to periodically reduce and increase circulating current within tuned portion 420. Alternatively, frequency may remain fixed, while shunt capacitor 412 is tuned in a systematic way to periodically vary resonant frequency f₀ of tuned portion 420. In at least one embodiment, resulting circulating current variations are same within tuned portion 420.

In at least one embodiment, by tuning tuned portion 420 to have a resonant frequency that is between 10% and 190% of applied RF frequency, a circulating current within tuned portion may be adjusted dynamically. In at least one embodiment, circulating current flowing within tuned portion 420 may be adjusted relative to a line current that flows through untuned portion 424 (e.g., line current does not circulate). In at least one embodiment, spatially confined currents flowing within tuned portion 420 and untuned portion 424 generate spatially resolved magnetic fields that are coupled to plasma 432. In at least one embodiment, spatial resolution of magnetic fields emanating from ICP antenna 408 enables a spatial distribution of ion currents within plasma 432.

In at least one embodiment, a ratio of circulating current flowing within tuned portion 420 to line current flowing within untuned portion 424 may be adjusted in two ways. First, by tuning resonant frequency f₀ of tuned portion 420. Second, by tuning applied RF frequency. By either method, in at least one embodiment, a ratio of applied RF frequency to resonant frequency of tuned portion 420 may be adjusted to be at least 1:10 and no greater than 10:1. In at least one embodiment, at a ratio of 1:1, applied RF frequency is equal to resonant frequency, and circulating current is at maximum magnitude. In at least one embodiment, resonance curve may be approximately symmetrical, so as ratio is increased or decreased from 1:1, magnitude of circulating current decreases on either side of resonance maximum.

In at least one embodiment, ratio of circulating current flowing within tuned portion 420 may be increased relative to line current flowing within untuned portion 424. In at least one embodiment, by adjusting applied RF frequency to be within 10% and 190% of tuned portion 420, ratio of circulating current in tuned portion 420 to line current flowing through untuned portion 424 may be greater than 1:1. In at least one embodiment, ratio of circulating current flowing within tuned portion 420 and line current flowing through untuned portion 424 may be 2:1 or greater by adjusting applied RF frequency to be 50% or greater of resonant frequency of tuned portion 420.

In above examples, applied RF frequency is adjusted relative to constant or fixed resonant frequency of tuned portion 420. In at least one embodiment, current ratio may also be adjusted by tuning resonant frequency of tuned portion 420 relative to a constant applied RF frequency. In at least one embodiment, resonant frequency of tuned portion 420 may be adjusted by tuning shunt capacitor 412.

In at least one embodiment, RF voltages on ICP antenna 408 generate electric fields that are coupled to plasma 432. In at least one embodiment, higher electric field strength leads to higher rates of ionization and ion density within plasma 432. In at least one embodiment, spatial distribution of strength of electric fields emanating from ICP antenna 408 can develop spatially differentiated ion densities within plasma 432. In at least one embodiment, RF voltages appearing across tuned portion 420 may be adjusted to be different from RF voltages appearing across untuned portion 424. In at least one embodiment, ion densities within regions of plasma 432 coupled to tuned portion 420 may be spatially differentiated from ion densities within regions of plasma 432 coupled to untuned portion 424.

In at least one embodiment, RF voltages across tuned portion 420 and untuned portion 424 may also be adjusted by tuning resonant frequency of tuned portion 420 relative to applied RF frequency. In at least one embodiment, applied RF frequency may be adjusted while resonant frequency of tuned portion 420 remains fixed. In at least one embodiment, by tuning resonant frequency of tuned portion 420, or by tuning applied frequency such that a ratio of applied frequency to resonant frequency of tuned portion 420 is at least 1:10, RF voltage across tuned portion 420 may be enhanced relative to RF voltage across untuned portion 424. In at least one embodiment, a ratio of RF voltages across tuned portion 420 and untuned portion 424 may be reduced to approximately 1:1 by adjusting radio of applied RF frequency and resonant frequency to 1:10 or less, or to 10:1 or greater.

FIG. 4B illustrates an exemplary plot 450 of current ratio between tuned portion 420 and untuned portion 424 of spatially tunable ICP antenna 408 as a function of applied RF frequency f, in accordance with at least one embodiment. In at least one embodiment, plot 450 may illustrate effect of spatially controlling resonances on ICP antenna 408. In at least one embodiment, curve of plot 450 may be low frequency shoulder of a steep resonance curve of tuned portion 420. In at least one embodiment, resonance curve may rise steeply as applied frequency approaches resonant frequency f₀. Here, frequency ratio is shown on horizontal axis, while ratio of circulating current flowing in a tuned portion (e.g., tuned portion 420) to line current flowing in an untuned portion (e.g., untuned portion 424) is shown on vertical axis.

Here, resonant frequency remains fixed while applied RF frequency is swept. In at least one embodiment, an assumed value of inductance L of a tuned coil segment (e.g., tuned portion 420) may be approximately 2.5 microhenries (uH). In at least one embodiment, a shunt capacitance across tuned coil segment (e.g., shunt capacitor 412) may have a capacitance of approximately 20 nanofarads (nF). Based on these values, for this circuit, tuned portion has a resonant frequency f₀ of approximately 715 kHz.

As can be seen from plot 450, in at least one embodiment, ratio of tuned portion current to untuned portion current increases to approximately 2:1 when applied RF frequency f is approximately 50% of f₀. In at least one embodiment, ratio increases to approximately 4:1 when applied RF frequency f is approximately 75% of f₀. In at least one embodiment, ICP antenna 408 may be operated at RF frequencies closer to gain larger current ratios if so desired. In at least one embodiment, ratio f/f₀ may be set at 1:1 to adjust magnitudes of circulating current within and RF voltage across tuned portion to maximum.

In at least one embodiment, ratio f/f₀ may be adjusted to be somewhat less than 1:1 to avoid instabilities. In at least one embodiment, an upper limit for f/f₀ may be limited to 0.90 to 0.95. In at least one embodiment, Q of tuned portions of ICP antenna 408 may be lowered to flatten resonance curve and extend operating frequency bandwidth. In at least one embodiment, lowering of Q may lower maximum magnitudes of circulating current and RF voltages.

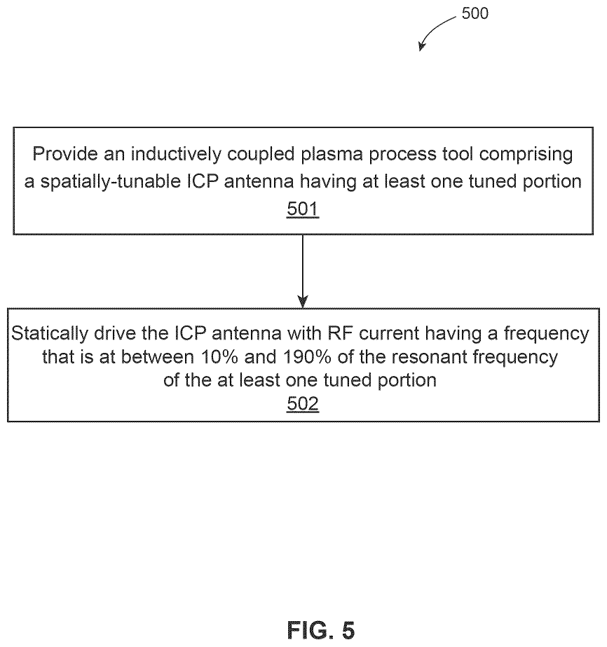

FIG. 5 illustrates a flow chart 500 summarizing an exemplary method for tuning a spatially tunable ICP antenna, such as ICP antenna 408, to enable static spatial control of a plasma, in accordance with at least one embodiment. At operation 501, a semiconductor process tool comprising a plasma chamber (e.g., plasma chamber 404) is provided. In at least one embodiment, semiconductor process tool may be similar to semiconductor process tool 400, shown in FIG. 4A. In at least one embodiment, semiconductor process tool may comprise an ICP antenna, such as ICP antenna 408. In at least one embodiment, ICP antenna comprises a plurality of inductive portions coupled in series, (e.g., as shown in RF circuit 200a). In at least one embodiment, at least one of inductive portions is coupled to a shunt capacitor, such as shunt capacitor 412, forming at least one tuned portion. In at least one embodiment, an RF signal source (e.g., RF signal source 204) may be coupled to ICP antenna to propagate an RF current into ICP antenna.

At operation 502, ICP antenna may be a coil antenna, as shown in FIGS. 3A and 3B, is driven at an applied RF frequency generated by RF signal source. In at least one embodiment, applied RF frequency may be within 10% and 190% of resonant frequency of one or more tuned portion of ICP antenna. In at least one embodiment, one or more tuned portions of ICP antenna may be tuned to develop at least a 1:1 ratio of circulating current within tank circuit(s) (of one or more tuned portions) to line current flowing through untuned portions of ICP antenna. In at least one embodiment, current ratio of 2:1 may be established by setting an applied RF frequency f that is approximately 50% of resonant frequency f₀ of tuned portion, in accordance with plot 450.

In at least one embodiment, a peripheral region of ICP antenna may comprise a tuned portion, whereas interior region of ICP antenna may comprise an untuned portion. In at least one embodiment, current ratio of 2:1 may be established at periphery of ICP antenna relative to current flowing through untuned interior region (e.g., untuned portion 424). In at least one embodiment, RF voltages across tuned periphery of ICP antenna may also be larger by a similar ratio than RF voltages across untuned interior portion of ICP antenna.

In at least one embodiment, plasma may be customized to have desired radial and/or azimuthal distributions of ion densities, voltages, and other plasma characteristics. In at least one embodiment, multiple (e.g., more than one) tuned portions may be present on ICP antenna. In at least one embodiment, a plasma (e.g., plasma 432) coupled to ICP antenna comprising multiple tuned portions may have correlated multiple zones of ion density and other plasma parameters. In at least one embodiment, plasma characteristics of multiple plasma zones may be controlled and adjusted relative to one another by f/f₀ ratio in multiple tuned portions of ICP antenna. Referring to illustrated embodiment shown in FIG. 4A, spatial distribution of densities of ions and/or other reactive species may be enhanced in periphery of plasma relative to interior region of plasma. In at least one embodiment, enhancement in ion concentration at periphery may equate to an increase rate of an etch or deposition process occurring on a periphery of a substrate, such as wafer 434 in FIG. 4A, relative to middle region.

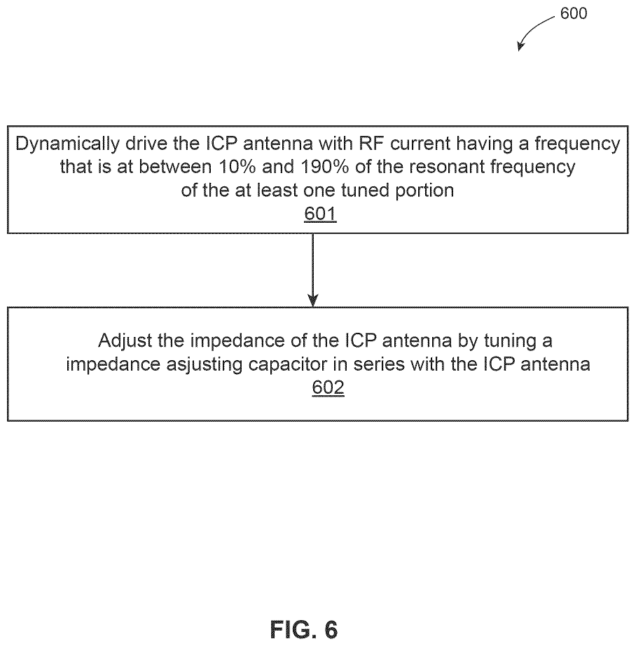

FIG. 6 illustrates a flow chart 600 summarizing an exemplary method for tuning a spatially tunable ICP antenna, such as ICP antenna 408, to enable dynamic spatial control of a plasma, in accordance with at least one embodiment. In at least one embodiment, at operation 601, tuned portions of ICP antenna can be dynamically tuned during a PECVD or plasma etch process. In at least one embodiment, dynamic tuning may be performed in response to random changes in plasma characteristics. In at least one embodiment, dynamic tuning may compensate fluctuations of precursor or plasma gas distributions over a substrate. In at least one embodiment, dynamic tuning may be performed in a pre-programmed manner. In at least one embodiment, dynamic tuning may comprise periodic tuning and detuning of adjacent tuned portions along an ICP antenna to dynamically shift regions of high ion density within a multizone plasma. In at least one embodiment, shifting of ion density from zone to zone may enable spatial control of deposition flux along a wafer substrate.

In at least one embodiment, deposition or etch non-uniformities introduced by a particular showerhead may be compensated by spatially controlling plasma. In at least one embodiment, a showerhead may have low deposition flux from a peripheral region. Under static plasma conditions, a deposited film may have a high non-uniformity, whereby film has a greater thickness in its periphery relative to its interior. In at least one embodiment, dynamic tuning of a multizone ICP antenna may periodically increase and decrease deposition flux in spatially differentiated zones (e.g., both interior portion and periphery) of a multizone plasma. In at least one embodiment, dynamic tuning may comprise periodically tuning and detuning tuned portions of ICP antenna. In at least one embodiment, spatial control of electromagnetic coupling along ICP antenna by such dynamic tuning may enable a more even film having low non-uniformity to be deposited. In at least one embodiment, dynamic tuning may be performed by dynamically adjusting shunt capacitances or by dynamically adjusting applied RF frequency.

At operation 602, in at least one embodiment, exemplary method includes regulating input impedance of ICP antenna by tuning a series capacitance coupled to ICP antenna (e.g., series capacitor 430 in FIG. 4A). In at least one embodiment, reactive component of input impedance of ICP antenna may depend on values of shunt capacitances across tuned portions of ICP antenna. As these values may be dynamically adjusted during course of a process, input impedance of ICP antenna may vary during course of a process and from one process to another. In at least one embodiment, series capacitance may be tuned to regulate input impedance of feed point of ICP antenna. In at least one embodiment, feed point impedance is frequency dependent, and may be predominantly capacitive reactance or inductive reactance depending on applied RF frequency.

In at least one embodiment, series capacitance may be in series with capacitance of ICP antenna, which may include shunt capacitances. If applied RF frequency is such that feed point impedance is predominantly inductive, in at least one embodiment, series capacitance may be adjusted to partially or completely cancel inductive reactance of ICP antenna, decreasing overall input impedance. In at least one embodiment, decreasing input impedance of ICP antenna. As input impedance of ICP antenna is decreased, for a given power level, peak input voltage of applied RF signal may also be decreased, lowering RF voltages across untuned portions of ICP antenna, in accordance with at least one embodiment.

In at least one embodiment, input impedance of ICP antenna feed point may be hundreds to thousands of ohms. In at least one embodiment, output impedance of RF signal source may be 50 ohms independent of frequency. In at least one embodiment, an impedance matching network having a set transformation ratio may be used to include between RF signal source output and input of ICP antenna to match a large impedance disparity that may exist. In at least one embodiment, series capacitance may be dynamically adjusted to maintain transformation ratio of impedance matching network by controlling feed point impedance of ICP antenna. In at least one embodiment, to lessen matching network transformation ratio and capacitive range, series capacitor may be adjusted to lower reactive component of input impedance to ICP antenna, reducing input impedance overall. In at least one embodiment, input voltage to ICP antenna may also be decreased. In at least one embodiment, voltage ratings of components in ICP antenna circuit may be reduced, potentially lowering capital and maintenance costs.

Following examples are provided that illustrate various embodiments. Here, examples can be combined with other examples. As such, various embodiments can be combined with other embodiments without changing scope of invention.

Example 1 is an apparatus, comprising an inductively coupled plasma (ICP) antenna comprising a plurality of inductances electrically coupled in series; and a capacitor coupled in parallel with an inductance of the plurality of inductances, wherein the ICP antenna is to be electromagnetically coupled to a plasma.

Example 2 includes all the features of example 1, wherein the inductance of the plurality of inductances is a first inductance, wherein the capacitor is a first capacitor of a plurality of capacitors, wherein the apparatus further comprises a second capacitor, and wherein the second capacitor is coupled in parallel with a second inductance of the plurality of inductances.

Example 3 includes all the features of example 2, wherein a third inductance of the plurality of inductances is between the first inductance and the second inductance.

Example 4 includes all the features of example 1, further comprising at least one series capacitor electrically coupled to an RF signal source and to the ICP antenna.

Example 5 includes all the features of example 4, wherein the at least one series capacitor is a fixed capacitor, a variable capacitor, or a combination thereof.

Example 6 includes all the features of example 2, wherein the first capacitor is further coupled in parallel with the first inductance and a fourth inductance, and wherein the fourth inductance and the first inductance are in electrical series with each other.

Example 7 includes all the features of example 6, wherein the second capacitor is coupled in parallel with the second inductance and a fifth inductance, and wherein the fifth inductance is of the plurality of inductances.

Example 8 is an apparatus, comprising an inductively coupled plasma (ICP) antenna comprising a coil, wherein the coil comprises a first terminal; a second terminal; and a plurality of coil segments between the first terminal and the second terminal; and a capacitor coupled in parallel with a coil segment of the plurality of coil segments.

Example 9 includes all the features of example 8, wherein the capacitor is above or below the coil segment.

Example 10 includes all the features of example 9, wherein the coil is a spiral coil, and wherein the spiral coil is substantially planar.

Example 11 includes all the features of example 10, wherein the capacitor is a first capacitor of a plurality of capacitors, wherein the coil segment is a first coil segment, and wherein individual ones of the plurality of capacitors are electrically coupled in parallel to one or more individual ones of the plurality of coil segments.

Example 12 includes all the features of example 11 wherein the first terminal of the first coil segment is at a first radius of the spiral coil, and the second terminal of the first coil segment is at a second radius of the spiral coil, and wherein the second radius is greater than the first radius, the spiral coil comprises a second coil segment, wherein the second coil segment comprises a third terminal and a fourth terminal, wherein the third terminal is electrically coupled to the second terminal, and wherein the fourth terminal is at a third radius of the spiral coil, the third radius is greater than the second radius; and the second coil segment is substantially concentric with the first coil segment.

Example 13 includes all the features of example 12, wherein the coil comprises a third coil segment, wherein the third coil segment is between the first coil segment and the second coil segment, and wherein the third coil segment is electrically coupled in series with the first coil segment and with the second coil segment.

Example 14 includes all the features of example 13, wherein the first capacitor is coupled to the first coil segment, wherein the apparatus comprises a second capacitor and a third capacitor, wherein the second capacitor is coupled to the second coil segment, and wherein the third capacitor is coupled to the third coil segment.

Example 15 includes all the features of example 14, wherein the ICP antenna comprises a first tuned portion that comprises the first capacitor electrically coupled in parallel to any one of the first coil segment, the second coil segment or the third coil segment, wherein the first coil segment has a first inductance, wherein the second coil segment has a second inductance, wherein the third coil segment has a third inductance, wherein the first capacitor of the plurality of capacitors has a first capacitance, and wherein the first tuned portion is operable to resonate at a first RF frequency.

Example 16 includes all the features of example 15, wherein the ICP antenna comprises a second tuned portion that comprises a second capacitor of the plurality of capacitors electrically coupled in parallel to any one of the first coil segment, the second coil segment or the third coil segment, wherein the second capacitor of the plurality of capacitors has a second capacitance, and wherein the second tuned portion is operable to resonate at a second RF frequency.

Example 17 includes all the features of example 16, wherein the ICP antenna comprises a third tuned portion that comprises a third capacitor of the plurality of capacitors electrically coupled in parallel to any one of the first coil segment, the second coil segment or the third coil segment, wherein the third capacitor of the plurality of capacitors has a third capacitance, and wherein the third tuned portion is operable to resonate at a third RF frequency.

Example 18 is a semiconductor process tool, comprising a first chamber; a second chamber, wherein the second chamber is adjacent to the first chamber, and wherein the second chamber is separated from the first chamber by a wall that comprises a dielectric material; an inductively coupled plasma (ICP) antenna within the first chamber, wherein the ICP antenna comprises a plurality of inductances, wherein individual ones of the plurality of inductances are electrically coupled in series to one another, wherein at least one inductance of the plurality of inductances is electrically coupled in parallel to a capacitor; and an RF signal source electrically coupled to the ICP antenna.

Example 19 is a method for tuning an inductively coupled plasma (ICP), comprising providing an ICP apparatus comprising an ICP antenna that comprises a plurality of inductances, wherein individual ones of the plurality of inductances are electrically coupled in series to one another, wherein at least one inductance of the plurality of inductances is electrically coupled in parallel to a capacitor; and a radio frequency (RF) signal source, wherein the ICP antenna is electrically coupled to the RF signal source, wherein the ICP antenna comprises at least one tuned portion, wherein the at least one tuned portion comprises a first inductance of the plurality of inductances coupled in parallel to the capacitor, wherein the at least one tuned portion comprises a tank circuit and has a resonant frequency, wherein the ICP antenna further comprises at least one untuned portion, and wherein the at least one untuned portion comprises a at least a second untuned inductance of the plurality of inductances electrically coupled to the at least one tuned portion of the ICP antenna; and driving the ICP antenna by tuning the RF signal source to a frequency such that a ratio of a first current that circulates within the at least one tuned portion and a second current that flows in a least one untuned portion is greater than 1:1, wherein a plasma coupled to the ICP antenna is spatially regulated, and wherein a rate of a plasma-enhanced process is spatially regulated across a substrate.

Example 20 includes all the features of example 19, wherein driving the ICP antenna by tuning the RF signal source comprises tuning the RF signal source to regulate a first electromagnetic field coupled to the tuned portion of the ICP antenna relative to a second electromagnetic field coupled to the untuned portion of the ICP antenna, wherein a first concentration of ions within a first portion of the plasma is regulated relative to a second concentration of ions within a second portion of the plasma, and wherein the second portion of the plasma is coupled to the untuned portion.

Example 21 includes all the features of example 20, further comprising tuning a series capacitance, wherein the series capacitance is series-coupled to the ICP antenna and to the RF signal source, wherein the series capacitance is tuned to regulate a capacitive reactance of the series capacitance, and wherein an input impedance of the ICP antenna is regulated by regulating the capacitive reactance of the series capacitance.

Example 22 includes all the features of example 21, wherein an input voltage to the ICP antenna is decreased by tuning the series capacitance to regulate the input impedance of the ICP antenna.

Example 23 is a process apparatus, comprising a vacuum process chamber and an inductively coupled plasma (ICP) antenna adjacent to the vacuum process chamber, wherein the ICP antenna comprises a radiative element, wherein the radiative element comprises one or more radio frequency (RF)-resonant sections, wherein a RF-resonant section comprises tank circuit comprising a capacitor electrically coupled to a segment of the radiative element.

Example 24 includes all features of example 23, wherein the capacitor is shunt capacitor coupled in parallel to the segment of the radiative element.

Example 25 includes all features of example 23, wherein the shunt capacitor is any one of a fixed capacitor, a variable capacitor, or a combination thereof.

Example 26 includes all features of example 23, wherein the radiative element comprises one or more un-tuned sections series coupled to the one or more RF resonant sections, wherein an untuned section comprises a non-resonant span of the radiating element.

Example 27 includes all features of example 26, wherein an untuned segment the one or more untuned segments is between two of the one or more RF-resonant sections.

Example 28 includes all features of example 23, further comprising at least one series capacitor coupled in series to the ICP antenna.

Example 29 includes all features of example 28, wherein the at least one series capacitor is a fixed capacitor, a variable capacitor, or a combination thereof.

Example 30 includes all features of example 23, wherein the radiative element comprises a coil, wherein the coil comprises one or more turns between an inner terminal and an outer terminal.

Example 31 includes all features of example 30, wherein the coil is a flat spiral coil or a helical coil.

Example 32 includes all features of example 30, wherein the one or more RF resonant segments comprise the capacitor coupled in shunt across a section of the radiative element, wherein the section of the radiative element comprises one or more turns of the coil.

Example 33 is an inductively coupled plasma (ICP) antenna, comprising a radiative element comprising a coil, wherein the coil comprises a first terminal; a second terminal; and one or more coil segments between the first terminal and the second terminal, wherein a coil segment comprises at least one coil winding; and one or more radio frequency (RF)-resonant sections, wherein a RF-resonant section comprises a capacitor coupled in parallel with a coil segment.

Example 34 includes all features of example 33, wherein the one or more capacitors is any one of a fixed capacitor, a variable capacitor or a combination thereof.

Example 35 includes all features of example 33, wherein the coil is a spiral coil, and wherein the spiral coil is substantially planar.

Example 36 includes all features of example 33, further comprising one or more untuned sections of the radiative element, wherein an untuned section comprises a non-resonant coil segment, and wherein the one or more untuned sections are adjacent to the one or more RF-resonant sections.

Example 37 includes all features of example 36, wherein the first capacitor is coupled to the first coil segment, wherein the apparatus comprises a second capacitor and a third capacitor, wherein the second capacitor is coupled to the second coil segment, and wherein the third capacitor is coupled to the third coil segment.

Example 38 includes all features of example 37, wherein the ICP antenna comprises a first tuned portion that comprises the first capacitor electrically coupled in parallel to any one of the first coil segment, the second coil segment or the third coil segment, wherein the first coil segment has a first inductance, wherein the second coil segment has a second inductance, wherein the third coil segment has a third inductance, wherein the first capacitor of the plurality of capacitors has a first capacitance, and wherein the first tuned portion is operable to resonate at a first RF frequency.

Example 39 is a method for tuning an inductively coupled plasma (ICP) comprising providing an ICP apparatus comprising an inductively coupled plasma (ICP) antenna comprising a coil, wherein the coil comprises a first terminal and a second terminal; and one or more coil segments between the first terminal and the second terminal; at least one tuned portion comprising a shunt capacitor coupled in parallel with at least one of the one or more coil segments; at least one untuned portion comprising at least one of the one or more coil segments that has no shunt capacitor; and a radio frequency (RF) signal source operable to output a driving frequency, wherein the ICP antenna is electrically coupled to the RF signal source; and driving the ICP antenna such that a ratio of a first current that circulates within the at least one tuned portion and a second current that flows in the at least one untuned portion is greater than 1:1, wherein a plasma coupled to the ICP antenna is spatially regulated, and wherein a rate of a plasma-enhanced process is spatially regulated across a substrate.

Example 40 includes all features of example 39, wherein driving the ICP antenna comprises tuning the driving frequency of the RF signal source, wherein the driving frequency is within 50% of the resonant frequency of the at least one tuned portion.

Example 41 includes all features of example 39, wherein driving the ICP antenna comprises tuning the at least one capacitor such that the resonant frequency of the at least one tuned circuit ranges between 10% and 190% of the driving frequency.

Example 42 includes all features of example 41, wherein tuning the at least one capacitor comprises varying a capacitance of the at least one capacitor during a course of a process, wherein the capacitance of the at least one capacitor is tuned manually or wherein the capacitance of the at least one capacitor is tuned dynamically during the course of the process.

Example 43 includes all features of example 39, further comprising adjusting an input impedance of the ICP antenna, wherein an adjustable capacitor is series-coupled to the ICP antenna is tuned to adjust the input impedance of the ICP antenna.

Besides what is described herein, various modifications may be made to the disclosed embodiments and implementations thereof without departing from their scope. Therefore, illustrations of embodiments herein should be construed as examples only, and not restrictive to the scope of the present disclosure. The scope of the invention should be measured solely by reference to the claims that follow.

1. An apparatus, comprising:
an inductively coupled plasma (ICP) antenna comprising a plurality of inductances electrically coupled in series; and
a capacitor coupled in parallel with an inductance of the plurality of inductances, wherein the ICP antenna is to be electromagnetically coupled to a plasma.

2. The apparatus of claim 1, wherein the inductance of the plurality of inductances is a first inductance, wherein the capacitor is a first capacitor of a plurality of capacitors, wherein the apparatus further comprises a second capacitor, and wherein the second capacitor is coupled in parallel with a second inductance of the plurality of inductances.

3. The apparatus of claim 2, wherein a third inductance of the plurality of inductances is between the first inductance and the second inductance.

4. The apparatus of claim 1, further comprising at least one series capacitor electrically coupled to an RF signal source and to the ICP antenna.

5. The apparatus of claim 4, wherein the at least one series capacitor is a fixed capacitor, a variable capacitor, or a combination thereof.

6. The apparatus of claim 2, wherein the first capacitor is further coupled in parallel with the first inductance and a fourth inductance, and wherein the fourth inductance and the first inductance are in electrical series with each other.

7. The apparatus of claim 6, wherein the second capacitor is coupled in parallel with the second inductance and a fifth inductance, and wherein the fifth inductance is of the plurality of inductances.

8. An apparatus, comprising:
an inductively coupled plasma (ICP) antenna comprising a coil, wherein the coil comprises:
a first terminal;
a second terminal;
a plurality of coil segments between the first terminal and the second terminal; and
a capacitor coupled in parallel with a coil segment of the plurality of coil segments.

9. The apparatus of claim 8, wherein the capacitor is above or below the coil segment.

10. The apparatus of claim 9, wherein the coil is a spiral coil, and wherein the spiral coil is substantially planar.

11. The apparatus of claim 10, wherein the capacitor is a first capacitor of a plurality of capacitors, wherein the coil segment is a first coil segment, and wherein individual ones of the plurality of capacitors are electrically coupled in parallel to one or more individual ones of the plurality of coil segments.

12. The apparatus of claim 11 wherein:
the first terminal of the first coil segment is at a first radius of the spiral coil, and the second terminal of the first coil segment is at a second radius of the spiral coil, and wherein the second radius is greater than the first radius;
the spiral coil comprises a second coil segment, wherein the second coil segment comprises a third terminal and a fourth terminal, wherein the third terminal is electrically coupled to the second terminal, and wherein the fourth terminal is at a third radius of the spiral coil;
the third radius is greater than the second radius; and
the second coil segment is substantially concentric with the first coil segment.

13. The apparatus of claim 12, wherein the coil comprises a third coil segment, wherein the third coil segment is between the first coil segment and the second coil segment, and wherein the third coil segment is electrically coupled in series with the first coil segment and with the second coil segment.

14. The apparatus of claim 13, wherein the first capacitor is coupled to the first coil segment, wherein the plurality of capacitors comprises a second capacitor and a third capacitor, wherein the second capacitor is coupled to the second coil segment, and wherein the third capacitor is coupled to the third coil segment.

15. The apparatus of claim 14, wherein the ICP antenna comprises a first tuned portion that comprises the first capacitor electrically coupled in parallel to any one of the first coil segment, the second coil segment or the third coil segment, wherein the first coil segment has a first inductance, wherein the second coil segment has a second inductance, wherein the third coil segment has a third inductance, wherein the first capacitor of the plurality of capacitors has a first capacitance, and wherein the first tuned portion is operable to resonate at a first RF frequency.

16. The apparatus of claim 15, wherein the ICP antenna comprises a second tuned portion that comprises the second capacitor of the plurality of capacitors electrically coupled in parallel to any one of the first coil segment, the second coil segment or the third coil segment, wherein the second capacitor of the plurality of capacitors has a second capacitance, and wherein the second tuned portion is operable to resonate at a second RF frequency.

17. The apparatus of claim 16, wherein the ICP antenna comprises a third tuned portion that comprises the third capacitor of the plurality of capacitors electrically coupled in parallel to any one of the first coil segment, the second coil segment or the third coil segment, wherein the third capacitor of the plurality of capacitors has a third capacitance, and wherein the third tuned portion is operable to resonate at a third RF frequency.

18. A semiconductor process tool, comprising:
a first chamber;
a second chamber, wherein the second chamber is adjacent to the first chamber, and wherein the second chamber is separated from the first chamber by a wall that comprises a dielectric material;
an inductively coupled plasma (ICP) antenna within the first chamber, wherein the ICP antenna comprises a plurality of inductances, wherein individual ones of the plurality of inductances are electrically coupled in series to one another, wherein at least one inductance of the plurality of inductances is electrically coupled in parallel to a capacitor; and
an RF signal source electrically coupled to the ICP antenna.

19. A method for tuning an inductively coupled plasma (ICP), comprising:
providing an ICP apparatus comprising:
an ICP antenna that comprises a plurality of inductances, wherein individual ones of the plurality of inductances are electrically coupled in series to one another, wherein at least one inductance of the plurality of inductances is electrically coupled in parallel to a capacitor;
a radio frequency (RF) signal source, wherein the ICP antenna is electrically coupled to the RF signal source, wherein the ICP antenna comprises at least one tuned portion, wherein the at least one tuned portion comprises a first inductance of the plurality of inductances coupled in parallel to the capacitor, wherein the at least one tuned portion comprises a tank circuit and has a resonant frequency, wherein the ICP antenna further comprises at least one untuned portion, and wherein the at least one untuned portion comprises a at least a second untuned inductance of the plurality of inductances electrically coupled to the at least one tuned portion of the ICP antenna; and
driving the ICP antenna by tuning the RF signal source to a frequency such that a ratio of a first current that circulates within the at least one tuned portion and a second current that flows in a least one untuned portion is greater than 1:1, wherein a plasma coupled to the ICP antenna is spatially regulated, and wherein a rate of a plasma-enhanced process is spatially regulated across a substrate.

20. The method of claim 19, wherein driving the ICP antenna by tuning the RF signal source comprises tuning the RF signal source to regulate a first electromagnetic field coupled to the at least one tuned portion of the ICP antenna relative to a second electromagnetic field coupled to the at least one untuned portion of the ICP antenna, wherein a first concentration of ions within a first portion of the plasma is regulated relative to a second concentration of ions within a second portion of the plasma, and wherein the second portion of the plasma is coupled to the at least one untuned portion.

21. The method of claim 20, further comprising tuning a series capacitance, wherein the series capacitance is series-coupled to the ICP antenna and to the RF signal source, wherein the series capacitance is tuned to regulate a capacitive reactance of the series capacitance, and wherein an input impedance of the ICP antenna is regulated by regulating the capacitive reactance of the series capacitance.

22. The method of claim 21, wherein an input voltage to the ICP antenna is decreased by tuning the series capacitance to regulate the input impedance of the ICP antenna.
